(19) United States
(12) Patent Application Publication
(10) Pub. No.: US 2021/0165623 A1
(43) Pub. Date: Jun. 3, 2021

(54) DISPLAY DEVICE AND DISPLAY METHOD

(71) Applicants: BOE TECHNOLOGY GROUP CO., LTD., Beijing (CN); Beijing BOE Display Technology Co., Ltd., Beijing (CN)

(72) Inventors: Xibin Shao, Beijing (CN); Dan Wang, Beijing (CN); Yun Qiu, Beijing (CN); Hebin Zhao, Beijing (CN); Shuai Liu, Beijing (CN)

(73) Assignees: BOE TECHNOLOGY GROUP CO., LTD., Beijing (CN); Beijing BOE Display Technology Co., Ltd., Beijing (CN)

(21) Appl. No.: 15/778,364

(22) PCT Filed: Dec. 11, 2017
(86) PCT No.: PCT/CN2017/115441

§ 371 Date: May 23, 2018

(30) Foreign Application Priority Data
Mar. 24, 2017 (CN) 201710183839.7

(51) Int. Cl. G06F 3/14; G09G 3/3208; G09G 3/36; G06F 3/147; G02F 1/1347; H01L 25/18; H01L 25/065; H01L 25/04

(52) U.S. Cl. CPC G06F 3/1423; G09G 3/3208; G09G 3/36; G06F 3/147; G02F 1/133602; H01L 25/18; H01L 25/0657; H01L 25/048; G09G 2360/04; G02F 1/1347

(57) ABSTRACT

A display device includes a first display panel and a second display. The second display panel of the display device is transparent, and the second display panel of the display device is configured to allow an image displayed on the first display panel to be visible through the second display panel.

### CROSS-REFERENCE TO RELATED APPLICATION

This PCT patent application claims priority to Chinese Patent Application No. 201710183839.7, filed on Mar. 24, 2017, the entire contents of which are incorporated herein by reference.

### TECHNICAL FIELD

The present disclosure generally relates to the field of display technologies and, more particularly, to a display device and a display method.

### BACKGROUND

Display devices can be classified into, for example, flat surface display devices and curved surface display devices according to shapes.

Flat surface display devices may include thin film transistor liquid crystal display (TFT-LCD) devices and organic light-emitting diode (OLED) display devices. A TFT-LCD panel is fabricated by pairing an array substrate and a color film substrate to form a cell. An OLED display panel is fabricated by forming, e.g., an anode, an organic light-emitting layer, a cathode, and other appropriate structures over a glass substrate.

### SUMMARY

In one aspect, the present disclosure provides a display device. The display device includes a first display panel and a second display. The second display panel is transparent, and the second display panel is configured to allow an image displayed on the first display panel to be visible through the second display panel.

In some embodiments, a gap distance between the first display panel and the second display panel is smaller than approximately 5 cm.

In some embodiments, a cavity is formed between the first display panel and the second display panel to accommodate an object.

In some embodiments, the cavity has a thickness ranging from approximately 300 mm to approximately 400 mm.

In some embodiments, the first display panel and the second display panel are configured to display different images.

In some embodiments, the display device further includes an image processing circuit. The image processing circuit is coupled to the first display panel and the second display panel, and is configured to provide different image signals to the first display panel and the second display panel.

In some embodiments, the image processing circuit includes a signal input sub-circuit and a signal decomposition sub-circuit. The signal input sub-circuit is configured to receive an original image signal. The signal decomposition sub-circuit is configured to decompose the original image signal to obtain a foreground image signal and a background image signal, and transmit the background image signal to the first display panel and transmit the foreground image signal to the second display panel.

In some embodiments, the image processing circuit includes a first signal input sub-circuit and a second signal input sub-circuit. The first signal input sub-circuit is configured to receive a background image signal and transmit the background image signal to the first display panel. The second signal input sub-circuit is configured to receive a foreground image signal and transmit the foreground image signal to the second display panel.

In some embodiments, the first display panel includes a liquid crystal display panel. The second display panel includes an organic light-emitting diode display panel. The display device further includes a direct backlight arranged on one side of the first display panel that faces away from the second display panel.

In some embodiments, a luminance of the direct backlight is greater than approximately 8000 nits.

In some embodiments, the first display panel includes a first liquid crystal display panel. The second display panel includes a second liquid crystal display panel. The display device further includes two edge-lit backlights each arranged at an edge of one of the first display panel or the second display panel.

In some embodiments, the first display panel includes a color film substrate. A color resist layer of the color film substrate includes a quantum dot material.

In some embodiments, the color film substrate is a first color film substrate. The second display panel includes a second color film substrate. A color resist layer of the second color film substrate includes a quantum dot material.

In some embodiments, the first display panel includes a first organic light-emitting diode display panel. The second display panel includes a second organic light-emitting diode display panel.

In some embodiments, the second display panel is approximately parallel to the first display panel.

In some embodiments, the display device further includes a housing configured to secure the first display panel and the second display panel.

Another aspect of the present disclosure provides a display method. The display method is for use in a display device. The display method includes obtaining different image signals; and transmitting the different image signals to the first display panel and the second display panel, respectively, such that the first display panel and the second display panel displays different images.

In some embodiments, the different image signals include a foreground image signal and a background image signal. Transmitting the different image signals to the first display panel and the second display panel, respectively, includes transmitting the background image signal to the first display panel, and transmitting the foreground image signal to the second display panel.

In some embodiments, obtaining the different image signals includes receiving an original image signal, and decomposing the original image signal to obtain the foreground image signal and the background image signal.

In some embodiments, obtaining the different image signals includes receiving the foreground image signal and the background image signal.

### BRIEF DESCRIPTION OF THE FIGURES

The following drawings are merely examples for illustrative purposes according to various disclosed embodiments and are not intended to limit the scope of the present disclosure.

FIG. 1 illustrates a side view of an exemplary display device according to various disclosed embodiments of the present disclosure;

FIG. 2 illustrates a schematic view of an exemplary display device including an exemplary first display panel and an exemplary second display panel displaying different images according to various disclosed embodiments of the present disclosure;

FIG. 3 illustrates a schematic view of an exemplary first display panel according to various disclosed embodiments of the present disclosure;

FIG. 4 illustrates a schematic view of an exemplary spectrum of light emitted by exemplary quantum dots according to various disclosed embodiments of the present disclosure;

FIG. 5 illustrates a schematic view of an exemplary display device serving as an display stand according to various disclosed embodiments of the present disclosure;

FIG. 6 illustrates a schematic view of an exemplary signal transmission process of a background image signal and a foreground image signal in an exemplary image processing circuit according to various disclosed embodiments of the present disclosure;

FIG. 7 illustrates a schematic view of another exemplary signal transmission process of a background image signal and a foreground image signal in another exemplary image processing circuit according to various disclosed embodiments of the present disclosure;

FIG. 8 illustrates a schematic view of another exemplary display device according to various disclosed embodiments of the present disclosure; and

FIG. 9 illustrates a flow chart of a display method according to various disclosed embodiments of the present disclosure.

### DETAILED DESCRIPTION

Exemplary embodiments of the disclosure will now be described in more detail with reference to the drawings. It is to be noted that, the following descriptions of some embodiments are presented herein for purposes of illustration and description only, and are not intended to be exhaustive or to limit the scope of the present disclosure.

The aspects and features of the present disclosure can be understood by those skilled in the art through the exemplary embodiments of the present disclosure further described in detail with reference to the accompanying drawings. The term “approximately” used herein indicates that the associated relationship may include a tolerance. The tolerance may be an allowable amount of variation of a quantity, such as 5%.

In conventional technologies, a flat surface display device cannot highlight layering in images because images displayed on a flat display panel of the flat surface display device are 2-dimensional.

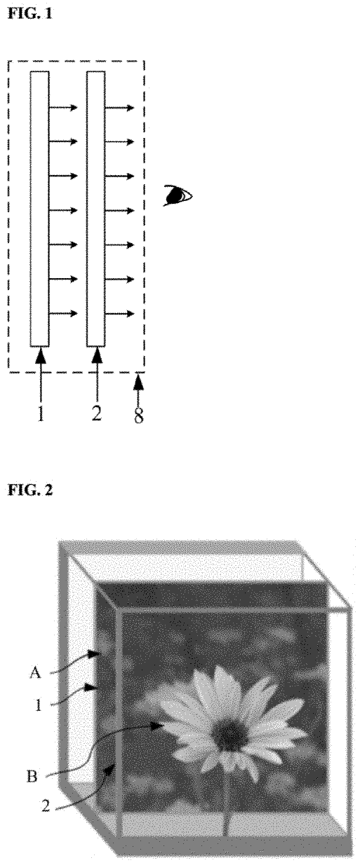

The present disclosure provides a display device. FIG. 1 illustrates a side view, e.g., a left-side view, of an exemplary display device 8 according to various disclosed embodiments of the present disclosure. As shown in FIG. 1, the display device 8 includes two display panels approximately parallel to each other.

The two display panels include a first display panel 1 and a second display panel 2, where the second display panel 2 may include a transparent display panel.

An image displayed by the first display panel 1 can be visible through the second display panel 2. That is, a light emitted by the first display panel 1 may be directed toward the second display panel 2 and at least a portion of the second display panel 2 may be transparent. For example, the second display panel 2 may include a transparent display panel. Further, images displayed by the two display panels may be different. For example, FIG. 2 illustrates a schematic view of an exemplary display device according to various disclosed embodiments of the present disclosure. As shown in FIG. 2, an image A displayed on the first display panel 1 is different from an image B displayed on the second display panel 2, and the image A displayed on the first display panel 1 is visible through the second display panel 2. When a user views images displayed by the display device, a distance between the image displayed on the first display panel 1 and the user is different from a distance between the image displayed on the second display panel 2 and the user. Thus, the user may sense layering in the images displayed by the display device, and thus may sense clear depth information.

In the display device consistent with the disclosure, two display panels may be arranged approximately parallel to each other, and the second display panel may include a transparent display panel. Thus, when the two display panels display different images, the first display panel can display an image visible through the second display panel, such that a user can see two images at different distances, which highlights image layering.

In some embodiments, the second display panel may include, for example, a transparent display panel. Different tees of transparent display panels can be used as the second display panel. The type of the first display panel may be selected according to the type of the second display panel. According to the type of the first display panel and the type of the second display panel, the display device of the present disclosure may include different structures.

In some embodiments, the first display panel may include a liquid crystal display panel, and the second display panel may include an organic light-emitting diode (OLED) display panel or a liquid crystal display panel. Further, a light-emitting layer of the OLED display panel may be formed by one or more OLEDs. The display device may further include a direct backlight arranged over a side of the first display panel facing away from the second display panel. That is, the first display panel may have a first side facing away from the second display panel, i.e., facing away from a user viewing the first display panel through the second display panel, and a second side facing toward the second display panel, and the direct backlight may be arranged over the first side that is facing away from the second display panel.

In some embodiments, a luminance of the direct backlight may be greater than approximately 8000 nits to ensure efficient display of the first display panel and the second display panel. Further, the direct backlight may allow backlight to evenly transmit to entire screens of the two display panels, and thus may make details of displayed images more realistic.

In some embodiments, when the second display panel is a liquid crystal display panel, the second display panel can share a backlight with the first display panel. That is, no additional backlight may be needed for the second display panel, such that electric energy consumption can be reduced. In some other embodiments, a separate backlight may be provided for the second display panel. In these embodiments, the backlight may include an edge-lit backlight, such that the backlight does not block contents displayed on the first display panel. The edge-lit backlight may be arranged on at least one side of the second display panel.

In some embodiments, the two display panels may both include liquid crystal display panels. The display device may further include two edge-lit backlights. The two edge-lit backlights and the two display panels may be in a one-to-one correspondence. That is, a first edge-lit backlight corresponding to the first display panel may be arranged on at least one side of the first display panel, and a second edge-lit backlight corresponding to the second display panel may be arranged on at least one side of the second display panel.

When the two display panels use separate edge-lit backlights, the two display panels can both be transparent display panels to realize two-side display. That is, the user can view images displayed in the display device from a side that is close to the first display panel, or view the images displayed in the display device from the other side that is closer to the second display panel. Further, because the edge-lit backlight may use a relatively smaller number of light-emitting diodes than the direct backlight, the edge-lit backlight may have a relatively low cost and a relatively low power consumption. In addition, because the edge-lit backlight may be arranged on one or more sides of the display panel, a thicknesses of the display panel can be reduced. Accordingly, a relatively thin display device may be realized.

In some embodiments, the two display panels may both include organic light-emitting diode (OLED) display panels. Accordingly, no backlight may need to be provided in the display device. As such, a thickness and an electric energy consumption of the display device can be reduced. When the two display panels are OLED display panels, the two display panels may both include transparent display panels, such that the display device can realize the two-side display.

In some embodiments, the first display panel may include a liquid crystal display panel, and the second display panel may include an OLED display panel. In addition, the display device may further include an edge-lit backlight, and the edge-lit backlight may be arranged on at least one side of the first display panel. Accordingly, because the first display panel may use the edge-lit backlight, the display device may have a relatively low cost, less power :consumption, and a relatively small thickness. Further, the two display panels may both include transparent display panels, such that the display device can realize the two-side display.

In some embodiments, the first display panel may include an OLED display panel and the second display panel may include a liquid crystal display panel. In these embodiments, the display device may further include an edge-lit backlight arranged on at least one side of the second display panel. Accordingly, because the second display panel may use the edge-lit backlight, the display device may have a relatively low cost, less power consumption, and a relatively small thickness. Further, the two display panels may both be transparent display panels, such that the display devices can realize the two-side display.

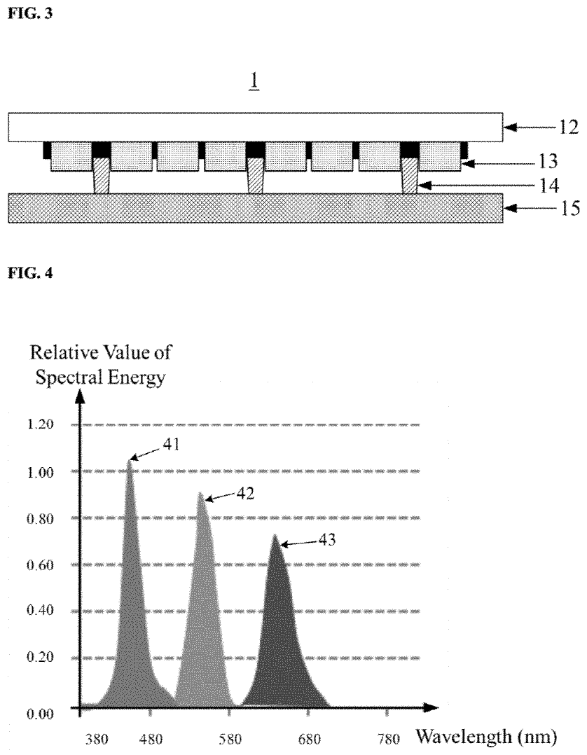

In some embodiments, when the first display panel is a liquid crystal display panel, the first display panel may include a color film substrate, and a color resist layer of the color film substrate may be formed by a material including a quantum dot (QD) material. FIG. 3 illustrates a schematic view of an example of the first display panel 1 according to various disclosed embodiments of the present disclosure. As shown in FIG. 3, the exemplary first display panel 1 includes a substrate 12, a color resist layer 13 formed by a material including a quantum dot material, a post spacer material 14, and a thin film transistor (TFT) array substrate 15. When a quantum dot is under electrical or optical stimulation, monochromatic light with a relatively high purity may be emitted, and a color of the monochromatic light may be adjusted by timing a diameter of the quantum dot. Thus, a luminous efficiency may be improved in the color film substrate formed of a material including a quantum dot. For example, a quantum dot with a diameter of approximately 3 nm can emit green light, a quantum dot with a diameter of approximately 2 nm can emit blue light, and a quantum dot with a diameter of approximately 7 nm can emit red light.

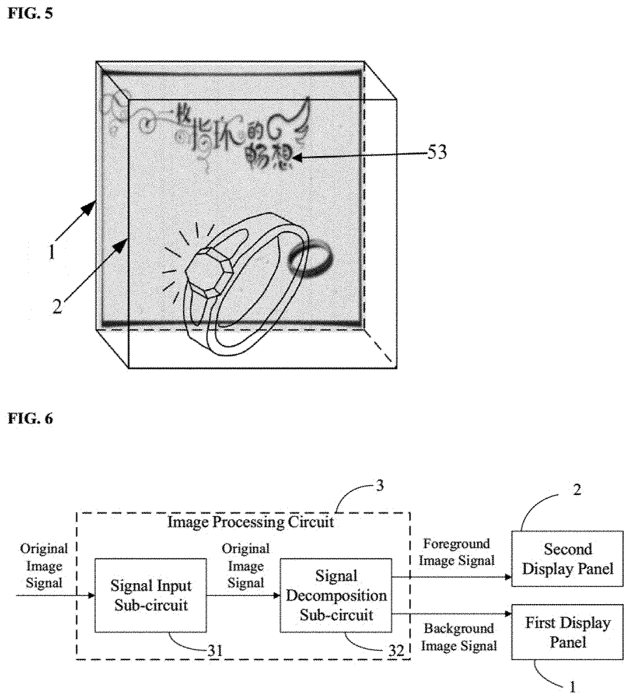

FIG. 4 illustrates a schematic view of an exemplary spectrum of light emitted by exemplary quantum dots according to various disclosed embodiments of the present disclosure. In FIG. 4, the horizontal axis of the spectrum represents a wavelength of the light in a unit of nm. The vertical axis of the spectrum represents a relative value of spectral energy. The relative value of spectral energy is dimensionless. That is, FIG. 4 illustrates a distribution of a relative value of spectral energy as a function of wavelength. Curve 41 represents an emission mainly including blue light, curve 42 represents an emission mainly including green light, and curve 43 represents an emission mainly including red light. In some embodiments, when the first display panel includes a color resist layer formed by a material including a quantum dot material and the first display panel is a liquid crystal display screen formed by an optical alignment process, a color gamut of a displayed image, i.e., a color range that can be displayed, can reach approximately 100%, a color resist light efficiency can reach approximately 90%, and a contrast can reach approximately 2000:1. Thus, when the first display panel includes a color resist layer formed by a material including a quantum dot material, color resist light efficiency may be improved, such that a user can view a clear image displayed on the first display panel through the second display panel. Further, because the color resist layer of the first display panel is formed by a material including a quantum dot material, the first display panel can operate at a relatively low voltage, and an energy consumption can be reduced. Further, because the quantum dot material may not be easily oxidized, a display lifetime of the first display panel may be relatively long.

Further, when the second display panel includes a liquid crystal display panel, the second display panel may also include a color film substrate, and a color resist layer of the color film substrate may be formed by a material including a quantum dot material. When the color resist layer is formed by a material including a quantum dot material, the color resist light efficiency may be improved. Further, when the second display panel includes a color resist layer formed by a material including a quantum dot material, and includes a liquid crystal having a high transmittance and a polarizer plate having a high light transmittance, a transmittance of the second display panel may exceed approximately 30%. The transmittance of the second display panel may be approximately three times of the transmittance of a conventional liquid crystal display screen using pigment color resists or dye color resists, i.e., producing the Red-Green-Blue (RGB) primary colors by filtering. In some embodiments, a high transmittance of the second display panel may allow the image displayed on the first display panel to be clearly transmitted through the second display panel.

In some embodiments, the first display panel or the second display panel may include a color resist layer formed by a material including a quantum dot material, or the first display panel and the second display panel each may include a color resist layer formed by a material including a quantum dot material. A fabrication process of making the color resist layer using a material including a quantum dot material may include, for example, dissolving the quantum dot material in a diluent, such that the quantum dot material is uniformly dispersed to form a quantum dot material solution, adding a resin material to the quantum dot material solution and stirring the quantum dot material solution evenly to form a colloidal quantum dot material, coating a layer of colloidal quantum dot material having a certain thickness over a substrate to form a quantum dot material layer, and forming a color resist layer by treating the quantum dot material layer using a patterning process. The patterning process may include photoresist coating, exposure, development, etching and photoresist peeling.

In some embodiments, the first display panel or the second display panel may include an OLED display panel, or the first display panel and the second display panel each may include an OLED display panel. A light-emitting layer of the OLED display panel may include one or more quantum dot light-emitting diodes (QLEDs), which is not restricted in the present disclosure.

The display device consistent with the disclosure may have various applications. In some embodiments, the display device may be configured to display images. Accordingly, a gap distance between the first display panel and the second display panel may be less than approximately 5 cm, such that a relatively better display performance of the display device may be ensured. In some other embodiments, the display device can be configured to serve as a display stand, a display window, or the like. Accordingly, parameters of the display device such as a thickness and a size of the display device are not restricted by parameters for a conventional display device. In the present disclosure, the parameters of the display device may be selected according to various application scenarios.

Further, a cavity for accommodating an object may be formed between the first display panel and the second display panel. In some embodiments, a thickness of the cavity may be configured to range from approximately 300 mm to approximately 400 mm, e.g., approximately 350 nm. Further, when an object is placed in the cavity, in some embodiments, one or both of the display panels of the display device may display images. In some embodiments, an image may be displayed in a certain portion of one of the two display panels by a certain control method. In some embodiments, one of the two display panels may display no image. The manner of displaying images in the display device may be selected according to various application scenarios, to highlight the object in the cavity, such that the object can have a better visual impression with or without a background image.

In some embodiments, the second display panel may not display, an image or may display an image in a transparent manner, and the first display panel may display a background image to highlight the object in the cavity. In some embodiments, the first display panel may not display an image or may display an image in a transparent manner, and the second display panel may display a foreground image to highlight the object in the cavity. In some embodiments, the first display panel and the second display panel each may display an image to highlight the object in the cavity. In some embodiments, an image may be displayed in a portion of the first display panel or the second display panel, and the other portion of the first display panel or the second display panel may not display an image to highlight the object in the cavity. In some embodiments, the object can be placed in the cavity, and the first display panel and the second display panel each may not display au image.

FIG. 5 illustrates a schematic view of an exemplary display device serving as a display stand according to various disclosed embodiments of the present disclosure. As shown FIG. 5, the display device serves as a display stand, and includes the first display panel 1, the second display panel 2, and a cavity between the first display panel 1 and the second display panel 2. A diamond ring is placed in the cavity. The first display panel 1 displays a background image including Chinese characters 53 meaning “a ring fantasy.” The diamond ring placed in the cavity appears more beautiful under the background image. As a result, viewers may be more willing to buy, and customer loyalty may be improved. In some other embodiments, the display device may serve as a display window in a shopping mall. The display window may also include a first display panel, a second display panel, and a cavity between the first display panel and the second display panel. When the display device serves as the display window, an object can be placed in the cavity, the second display panel may display an image for flattering the scene, e.g., mist, and the first display panel may display certain multicolor patterns. Accordingly, the object in the cavity may be displayed in the display window in a relatively fantasy manner.

In the present disclosure, in order to ensure an effective display of images on the display device, the display device may further include an image processing circuit coupled to the first display panel and the second display panel. The image processing circuit may be configured to provide different image signals to the first display panel and the second display panel.

According to the manner in which the image processing circuit provides signals to the first display panel and the second display panel, the image processing circuit may include, for example, different structures as described below.

For example, FIG. 6 illustrates a schematic view of an exemplary signal transmission process of a background image signal and a foreground image signal in an exemplary image processing circuit 3 according to various disclosed embodiments of the present disclosure. As shown in FIG. 6, the image processing circuit 3 includes a signal input sub-circuit 31 and a signal decomposition sub-circuit 32. The signal input sub-circuit 31 is configured to receive an original image signal. The signal decomposition sub-circuit 32 is configured to decompose the original image signal to obtain a foreground image signal and a background image signal, and transmit the background image signal to the first display panel 1 and transmit the foreground image signal to the second display panel 2, such that the first display panel 1 and the second display panel 2 display a background image and a foreground image, respectively.

In some embodiments, pixels in the background image may have different gray scale as compared to pixels in the foreground image. For example, a gay scale range of the pixels in the background image may be relatively narrow, and a gay scale range of the pixels in the foreground image may be relatively wide. Thus, when the signal decomposition sub-circuit decomposes the original image signal, a gay scale range threshold can be preset according to the gray scale feature of the foreground image and the background image. Further, pixels in the original image can be screened according to the preset gay scale range threshold to obtain the pixels of the background image and the pixels of the foreground image. Accordingly, an original image signal may be decomposed into a background image signal and a foreground image signal.

In some embodiments, image contents in the background image may be the same as or similar to each other, and thus may have a low-rank property, e.g., a property corresponding to a low-rank matrix. Further, image contents in the foreground image may be different from the image contents in the background image, and may have a sparse property, e.g., a property corresponding to a sparse matrix. Thus, according to the properties of the foreground image and the background image, a background modeling method or another appropriate method may be applied to the original image signal to decompose a matrix of the original image signal into a low-rank matrix and a sparse matrix. The low-rank matrix may correspond to the background image signal, and the sparse matrix may correspond to the foreground image signal. Accordingly, the original image signal may be decomposed into the background image signal and the foreground image signal.

In some embodiments, the background image may contain relatively more types of image contents and the image contents may be complicated, and the foreground image may contain relatively fewer types of image contents. By using an edge detection method, an obtained foreground image may have a relatively sharper edge than an obtained background image. Thus, when the original image signal is decomposed, obtained image edges may be processed to obtain the relatively sharper image edge corresponding to the foreground image signal. Then, a connected-region marker algorithm may be applied to the obtained image edges to obtain a foreground image signal in the original image signal. Further, by applying a subtraction method on the original image signal and the obtained foreground image signal, a background image signal may be obtained. Accordingly, the original image signal may be decomposed into the background image signal and the foreground image signal.

In some embodiments, the original image signal may be decomposed into a background image signal and a foreground image signal using another appropriate method, which is not restricted in the present disclosure.

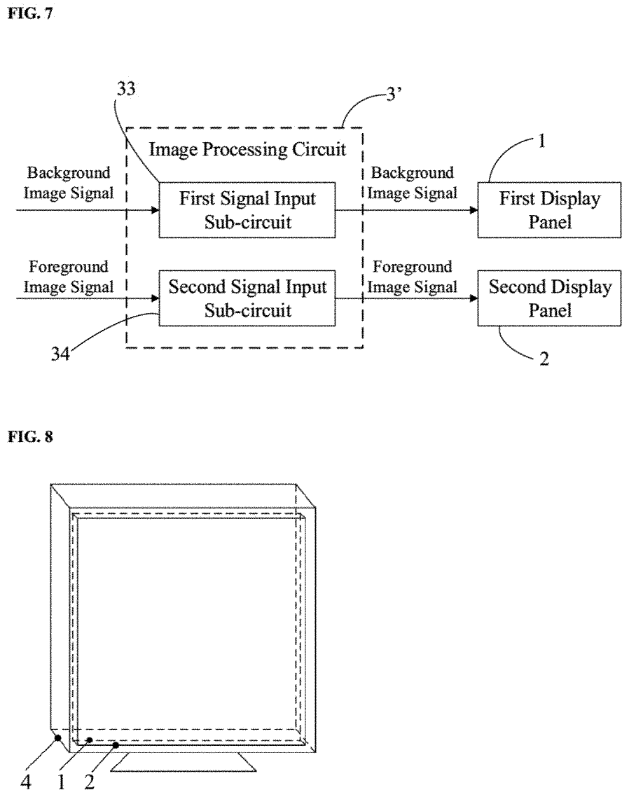

For example, FIG. 7 illustrates a schematic view of another exemplary signal transmission process of a background image signal and a foreground image signal in another exemplary image processing circuit 3′ according to various disclosed embodiments of the present disclosure. As shown in FIG. 7, the image processing circuit 3′ includes a first signal input sub-circuit 33 and a second signal input sub-circuit 34. The first signal input sub-circuit 33 is configured to receive a background image signal and to transmit the background image signal to the first display panel 1, such that the first display panel 1 displays a background image. The second signal input sub-circuit 34 is configured to receive a foreground image signal and transmit the foreground image signal to the second display panel 2, such that the second display panel 2 displays a foreground image.

In the present disclosure, the display device consistent with the disclosure may further include other appropriate structures. FIG. 8 illustrates a schematic view of another exemplary display device according to various disclosed embodiments of the present disclosure. As shown in FIG. 8, the display device further includes a housing 4 for securely placing the two display panels. The housing 4 is configured to ensure that the first display panel 1 and the second display panel 2 can be effectively and securely placed.

In the display device of the disclosure, two display panels may be approximately parallel to each other, and the second display panel may include a transparent display panel. Thus, when the two display panels display different images, the first display panel can display an image visible through the second display panel, such that a user can see two images at different distances, which highlights image layering.

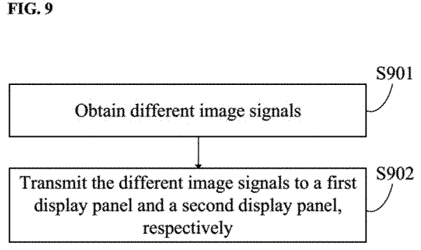

The present disclosure provides a display method. The display method can be applied to, for example, the display device shown in FIG. 1 or FIG. 5. FIG. 9 illustrates a flow chart of a display method according to various disclosed embodiments of the present disclosure. As shown in FIG. 9, the display method includes obtaining different image signals, and transmitting the different image signals to a first display panel and a second display panel, respectively, such that the first display panel and the second display panel display the different images, respectively.

In the display method of the disclosure, two display panels may be approximately parallel to each other, and the second display panel may include a transparent display panel. Thus, when the two display panels are controlled to display different images, the first display panel can display an image visible through the second display panel, such that a user can see two images at different distances, which highlights image layering.

Various methods can be used for obtaining the different image signals.

In some embodiments, obtaining the different image signals may include receiving an original image signal, decomposing the original image signal to obtain a foreground image signal and a background image signal. For signal transfer process, reference can be made to FIG. 6.

In some other embodiments, obtaining the different image signals may include receiving a foreground image signal and a background image signal. For signal transfer process, reference can be made to FIG. 7.

The obtained different image signals may include the foreground image signal and the background image signal. Thus, transmitting the different image signals to the first display panel and the second display panel, respectively, may include transmitting the background image signal to the first display panel, such that the first display panel displays the background image; and transmitting the foreground image signal to the second display panel, such that the second display panel displays the foreground image.

In the display method of the disclosure, two display panels may be approximately parallel to each other, and the second display panel may include a transparent display panel. Thus, when the two display panels are controlled to display different images, the first display panel can display an image visible through the second display panel, such that a user can see two images at different distances, which highlights image layering.

The present disclosure provides a display device and a display method. The display device may include two display panels that are approximately parallel to each other. The two display panels may include a first display panel and a second display panel. The second display panel may include a transparent display panel. The first display panel can display an image visible through the second display panel. Images displayed by the two display panels may be different. The display device consistent with the present disclosure can highlight layering in images.

The foregoing description of the embodiments of the disclosure has been presented for purposes of illustration and description. It is not intended to be exhaustive or to limit the disclosure to the precise form or to exemplary embodiments disclosed. Accordingly, the foregoing description should be regarded as illustrative rather than restrictive. Obviously, many modifications and variations will be apparent to persons skilled in this art. The embodiments are chosen and described in order to explain the principles of the technology, with various modifications suitable to the particular use or implementation contemplated. It is intended that the scope of the invention be defined by the claims appended hereto in which all terms are meant in their broadest reasonable sense unless otherwise indicated. Therefore, the term “the disclosure,” “the present disclosure” or the like does not necessarily limit the claim scope to a specific embodiment, and the reference to exemplary embodiments of the disclosure does not imply a limitation on the invention, and no such limitation is to be inferred. Moreover, the claims may refer to “first,” “second,” etc., followed by a noun or element. Such terms should be understood as a nomenclature and should not be construed as giving the limitation on the number of the elements modified by such nomenclature unless specific number has been given. Any advantages and benefits described may or may not apply to all embodiments of the disclosure. It should be appreciated that variations may be made to the embodiments described by persons skilled in the art without departing from the scope of the present disclosure. Moreover, no element or component in the present disclosure is intended to be dedicated to the public regardless of whether the element or component is explicitly recited in the following claims.

1. A display device, comprising:
a first display panel, and
a second display panel that is transparent and configured to allow an image displayed on the first display panel to be visible through the second display panel.

2. The display device according to claim 1, wherein a gap distance between the first display panel and the second display panel is smaller than approximately 5 cm.

3. The display device according to claim 1, wherein a cavity is formed between the first display panel and the second display panel to accommodate an object.

4. The display device according to claim 3, wherein the cavity has a thickness ranging from approximately 300 mm to approximately 400 mm.

5. The display device according to claim 1, wherein the first display panel and the second display panel are configured to display different images.

6. The display device according to claim 5, further comprising:
an image processing circuit coupled to the first display panel and the second display panel, and configured to provide different image signals to the first display panel and the second display panel.

7. The display device according to claim 6, wherein the image processing circuit includes:
a signal input sub-circuit configured to receive an original image signal; and
a signal decomposition sub-circuit configured to:
decompose the original image signal to obtain a foreground image signal and a background image signal, and
transmit the background image signal to the first display panel and transmit the foreground image signal to the second display panel.

8. The display device according to claim 6, wherein the image processing circuit includes:
a first signal input sub-circuit configured to receive a background image signal and transmit the background image signal to the first display panel; and
a second signal input sub-circuit configured to receive a foreground image signal and transmit the foreground image signal to the second display panel.

9. The display device according to claim 1,
wherein:
the first display panel includes a liquid crystal display panel, and
the second display panel includes an organic light-emitting diode display panel,
the display device further comprising:
a direct backlight arranged on one side of the first display panel that faces away from the second display panel.

10. The display device according to claim 9, wherein a luminance of the direct backlight is greater than approximately 8000 nits.

11. The display device according to claim 1,
wherein:
the first display panel includes a first liquid crystal display panel, and
the second display panel includes a second liquid crystal display panel,
the display device further comprising:
two edge-lit backlights each arranged at an edge of one of the first display panel or the second display panel.

12. The display device according to claim 1, wherein:
the first display panel includes a color film substrate, and
a color resist layer of the color film substrate includes a quantum dot material.

13. The display device according to claim 12, wherein:
the color film substrate is a first color film substrate,
the second display panel includes a second color film substrate, and
a color resist layer of the second color film substrate includes a quantum dot material.

14. The display device according to claim 1, wherein:
the first display panel includes a first organic light-emitting diode display panel, and
the second display panel includes a second organic light-emitting diode display panel.

15. The display device according to claim 1, wherein the second display panel is approximately parallel to the first display panel.

16. The display device according to claim 1, further comprising a housing configured to secure the first display panel and the second display panel.

17. A display method, for use in the display device according to claim 1, comprising:
obtaining different image signals; and
transmitting the different image signals to the first display panel and the second display panel, respectively, such that the first display panel and the second display panel displays different images.

18. The method according to claim 17, wherein:
the different image signals include a foreground image signal and a background image signal; and
transmitting the different image signals to the first display panel and the second display panel, respectively, includes:
transmitting the background image signal to the first display panel, and
transmitting the foreground image signal to the second display panel.

19. The method according to claim 18, wherein obtaining the different image signals includes:
receiving an original image signal, and
decomposing the original image signal to obtain the foreground image signal and the background image signal.

20. The method according to claim 18, wherein obtaining the different image signals includes receiving the foreground image signal and the background image signal.
